(19) United States
(12) Patent Application Publication
(10) Pub. No.: US 2012/0187436 A1
(43) Pub. Date: Jul. 26, 2012

(54) LIGHT EMITTING DIODE DEVICE AND MANUFACTURING METHOD THEREOF

(75) Inventors: PIN-CHUAN CHEN, Hukou (TW); HSIN-CHIANG LIN, Hukou (TW); WEN-LIANG TSENG, Hukou (TW)

(73) Assignee: ADVANCED OPTOELECTRONIC TECHNOLOGY, INC., Hsinchu Hsien (TW)

(21) Appl. No.: 13/306,809

(22) Filed: Nov. 29, 2011

(30) Foreign Application Priority Data
Jan. 24, 2011 (CN) 201110024973.5

(51) Int. Cl. H01L 33/52; H01L 33/60

(52) U.S. Cl. 257/98; 438/28; 257/E33.059

(57) ABSTRACT

A light emitting diode (LED) device includes a substrate, a supporting member, an electrode layer, an LED chip and an encapsulant. The substrate has a first surface and a second surface. The substrate defines a hole extending through the first surface and the second surface. The supporting member is attached to the second surface of the substrate and covers the hole. The supporting member and the substrate cooperatively define a cavity. The electrode layer is arranged on the first surface of the substrate and an inner surface of the cavity. The encapsulant is arranged on the electrode layer and covers the LED chip.

### BACKGROUND

1. Technical Field

The present disclosure generally relates to solid state light emitting devices and, more particularly, to a light emitting diode (LED) device and manufacturing method thereof.

2. Discussion of Related Art

LEDs have many advantages, such as high luminosity, low operational voltage, low power consumption, compatibility with integrated circuits, easy driving, long term reliability, and environmental friendliness which have promoted the wide use of LEDs as a light source.

Generally, an LED device includes a substrate, an LED, a reflective cup, and an electrode layer formed on an upper surface of the substrate. The LED is received in the reflective cup and electrically connected to the electrode layer. A height of the reflective cup is greater than that of the LED, therefore, light emitted from the LED can be reflected outward by the reflective cup for illuminating. However, the LED device is fairly thick resulting from the size of the substrate and the reflector.

Therefore, what is needed is an LED device and manufacturing method thereof which can overcome the described limitations.

### BRIEF DESCRIPTION OF THE DRAWINGS

FIG. 1 is a cross-sectional view of an LED device, in accordance with a first embodiment of the present disclosure.

FIG. 2 is a cross-sectional view of an LED device, in accordance with a second embodiment of the present disclosure.

FIG. 3 to FIG. 7 are cross-sectional views showing different steps of an embodiment of a method for manufacturing the LED of FIG. 1.

### DETAILED DESCRIPTION OF EMBODIMENTS

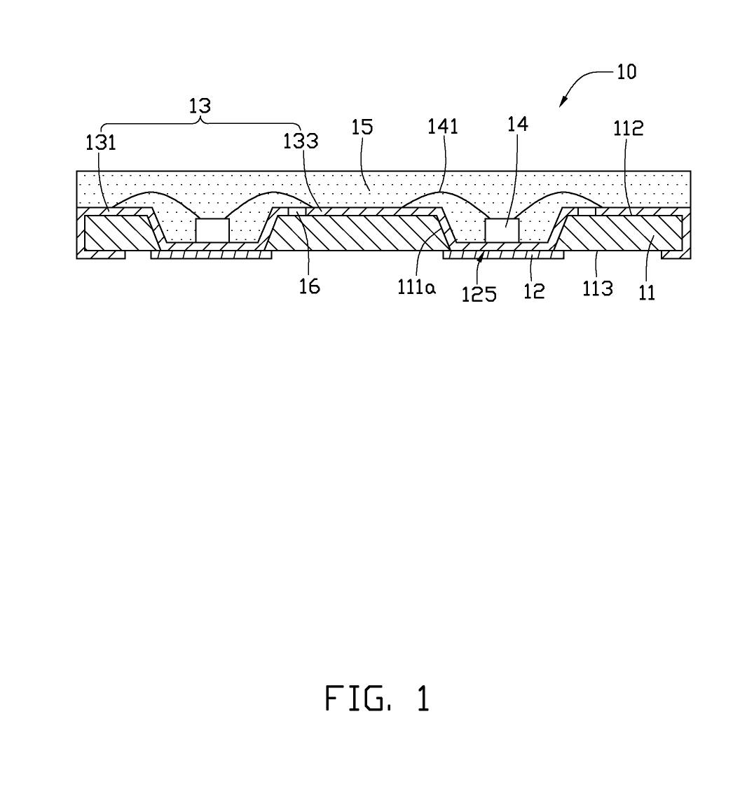

Referring to FIG. 1, an LED device 10, in accordance with a first embodiment, is provided. The LED device 10 includes a substrate 11, a plurality of supporting members 12, an electrode layer 13, a plurality of LED chips 14 and an encapsulant 15.

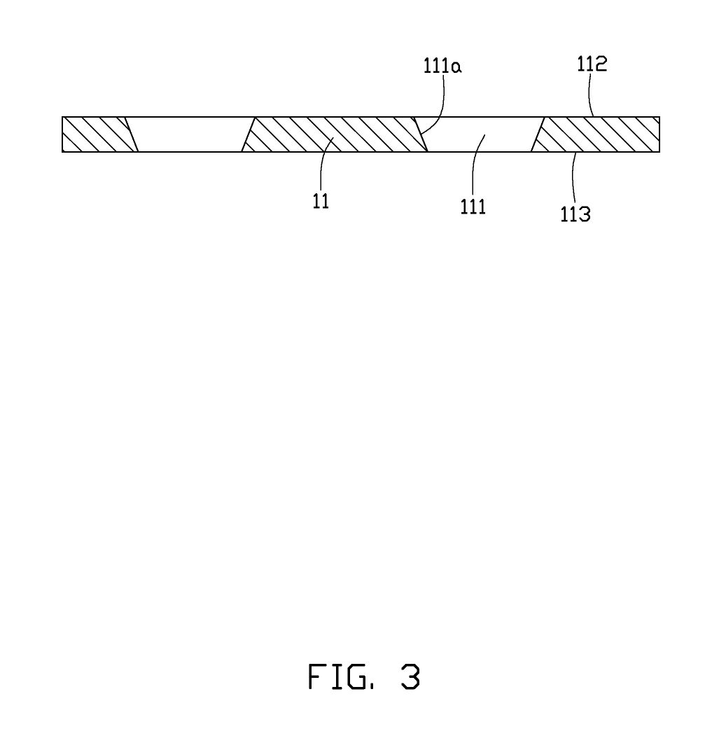

Referring to FIGS. 3-5 also, the substrate 11 is thin and flat, and includes a first surface 112 and a second surface 113 opposite to the first surface 112. The substrate 11 defines a plurality of holes 111 penetrating through the first surface 112 and the second surface 113. In the present embodiment, each of the holes 111 includes an inclined side surface 111a. A size (i.e., width or diameter) of the hole 111 gradually increases along a direction from the second surface 113 towards the first surface 112. The substrate 11 can be made of Bismaleimide Triazine resin (BT resin). A thickness of the substrate 11 ranges from 60 to 300 microns, which is larger than a common LED chip.

The supporting members 12 are attached to the second surface 113 of the substrate 11 to cover the holes 111, respectively. Each supporting member 12 includes an upper surface 125 adjacent to and connected to the second surface 113 of the substrate 11. The supporting members 12 and the substrate 11 cooperatively define a plurality of cavities 17 for receiving the LED chips 14. A cross-section of each cavity 17 is trapezium-shaped. The supporting members 12 can be made of metal with high thermal conductivity selected from a group consisting of aurum, silver, copper, platinum, aluminum, nickel, stannum, magnesium and combination thereof. In the present embodiment, the supporting members 12 are made of copper. A thickness of the supporting member 12 ranges from 30 to 150 microns.

The electrode layer 13 is formed on the first surface 112 of the substrate 11, the side surfaces 111a, and the parts of the upper surfaces 125 of supporting member 12 exposed in the holes 111. In the present embodiment, the electrode layer 13 includes a plurality of electrode units corresponding to the LED chips 14. Each electrode unit includes a first electrode 131 and a second electrode 133. The first electrode 131 and the second electrode 133 of each electrode unit are spaced from each other by a hole 16 defined therebetween. In this embodiment, the first electrode 131 covers the side surface 111a and the upper surfaces 125, i.e., inner surfaces of the substrate 11 and the supporting member 12 surrounding the cavity 17. The second electrode 133 of each electrode unit is connected to the first electrode 131 of an adjacent electrode unit. The electrode layer 13 can be selected from a group consisting of aurum, silver, copper, platinum, aluminum, nickel, stannum, magnesium and combination thereof.

The LED chips 14 are respectively received in the cavities 17. Each LED chip 14 is electrically connected to the first electrode 131 and the second electrode 133 of one corresponding electrode unit via two wires 141.

The encapsulant 15 is arranged on the electrode layer 13 and covers the LED chips 14. The encapsulant 15 can be made of transparent materials, such as silicone, or epoxy resin. In the present embodiment, phosphor material can be doped into the encapsulant 15 to convert the wavelength of light emitted from the LED chip 14.

The portions of electrode layer 13 in the cavity 17 act as a reflective cup to reflect light emitted from the LED chips 14, thereby improving a light extraction efficiency of the LED device 10. Accordingly, the LED device 10 does not need other reflective cup on the substrate 11, and the height of the LED device 10 is reduced thereby.

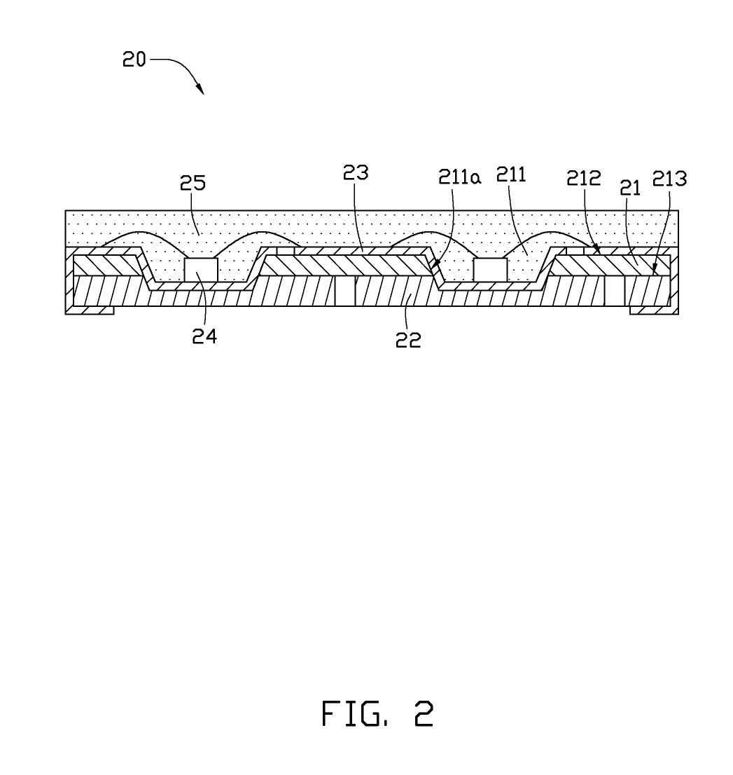

Referring to FIG. 2, an LED device 20 in accordance with a second embodiment of the present disclosure is illustrated. The LED device 20 includes a substrate 21, a plurality of supporting members 22 attached to a second surface 213 of the substrate 21, an electrode layer 23, a plurality of LED chips 24 and an encapsulant 25. In this embodiment, the supporting member 22 covers the second surface 213 of the substrate 21, and side surfaces of the supporting member 22 are coplanar with side surfaces of the substrate 21. Holes 211 penetrate through the substrate 21 and then extend to an upper portion of the supporting members 22. The electrode layer 23 covers a first surface 212 of the substrate 21 and side surfaces 211a of the substrate 21 and supporting member 22 surrounding the holes 211. The LED chips 24 are disposed in the holes 211 electrically connected to the electrode layer 23. Since the holes 211 extend into the supporting member 22, the side surface 211a surrounding the hole 211 can have the same height even if the total height of the LED device 20 is reduced. That is, the entire height of the LED device 20 can be further reduced without reducing light extraction efficiency thereof.

Referring to FIGS. 3 to 7, a method for manufacturing the LED device 10 in accordance with an exemplary embodiment is also disclosed, which includes the following steps.

Referring to FIG. 3, the first step is to provide a thin substrate 11 with holes 111 extending therethrough.

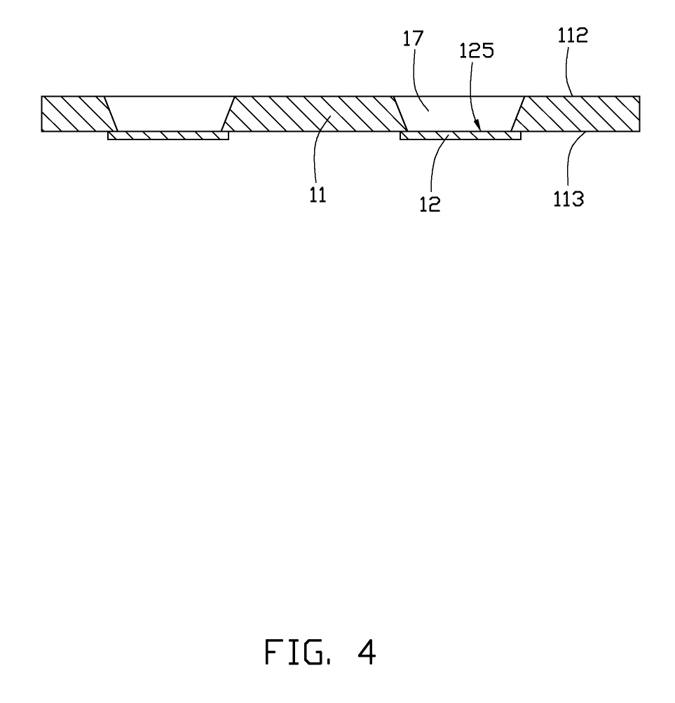

Referring to FIG. 4, the second step is to form a plurality of supporting members 12 on the second surface 113 of the substrate 11 to cover bottoms of the holes 111, respectively. The supporting members 12 and the substrate 11 cooperatively define a plurality of cavities 17. A cross-section of each cavity is trapezium-shaped. Alternatively, the supporting members 12 can be a flat board, as described in the LED device 20 shown in FIG. 2.

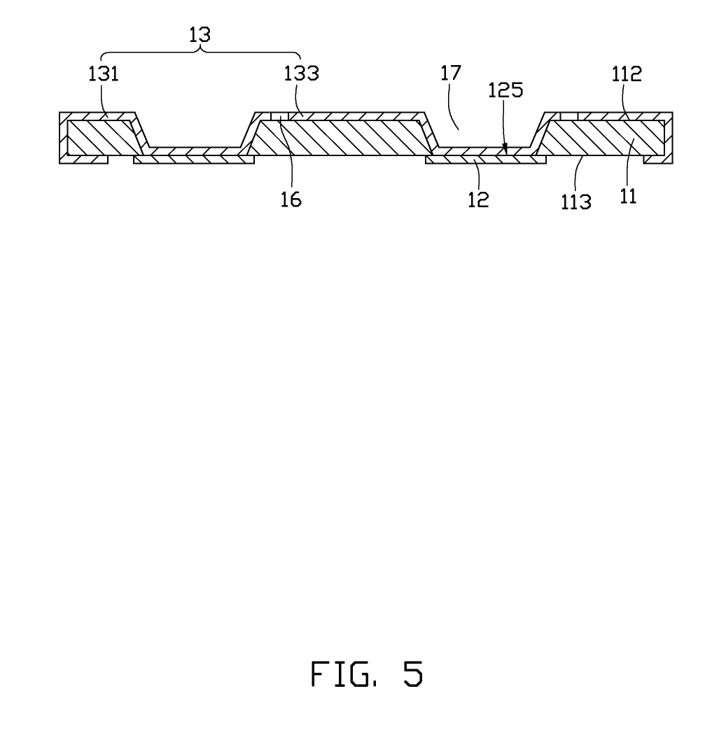

Referring to FIG. 5, the third step is to form an electrode layer 13 on the substrate 11, and traversing the holes 111 and the supporting member 12. In the present embodiment, the electrode layer 13 includes a plurality of electrode units corresponding to the LED chips 14. Each electrode unit includes a first electrode 131 and a second electrode 133. The first electrode 131 is formed on the upper surface 125 of the supporting member 12, the side surface 111a of the holes 111 and the first surface 112 of the substrate 11, and extends from the first surface 112 of the substrate 11 to the second surface 113 thereof along a peripheral edge of the substrate 11. The second electrode 133 is formed at a side of the hole 111 opposite to the first electrode 131, and insulated from the first electrode 131.

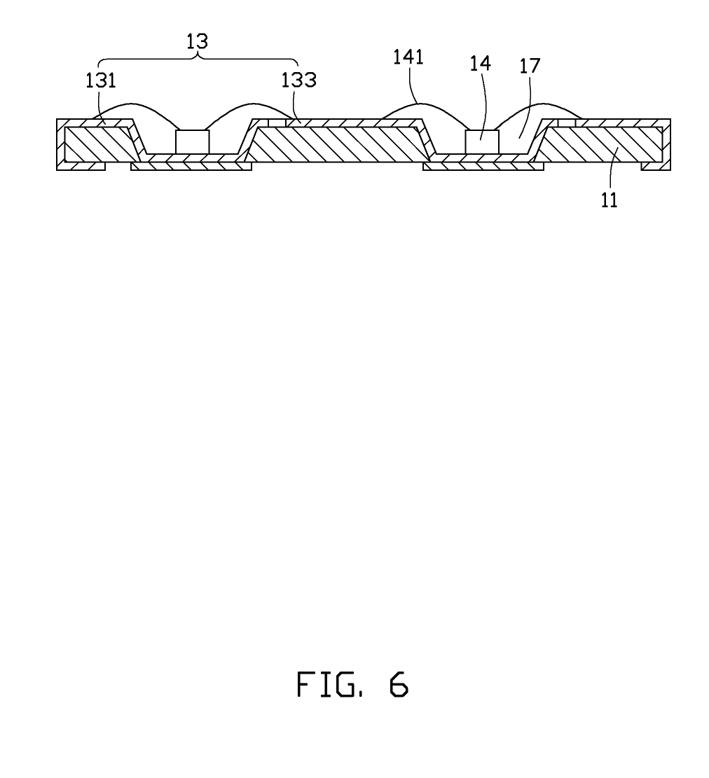

Referring to FIG. 6, the fourth step is to arrange a plurality of LED chips 14 on the electrode layer 13, with each LED chip 14 received in a cavities 17. Each LED chip 14 is electrically connected to the corresponding first electrode 131 and the second electrode 133 via two wires 141. In the present embodiment, a height of the substrate 11 is greater than that of the LED chip 14.

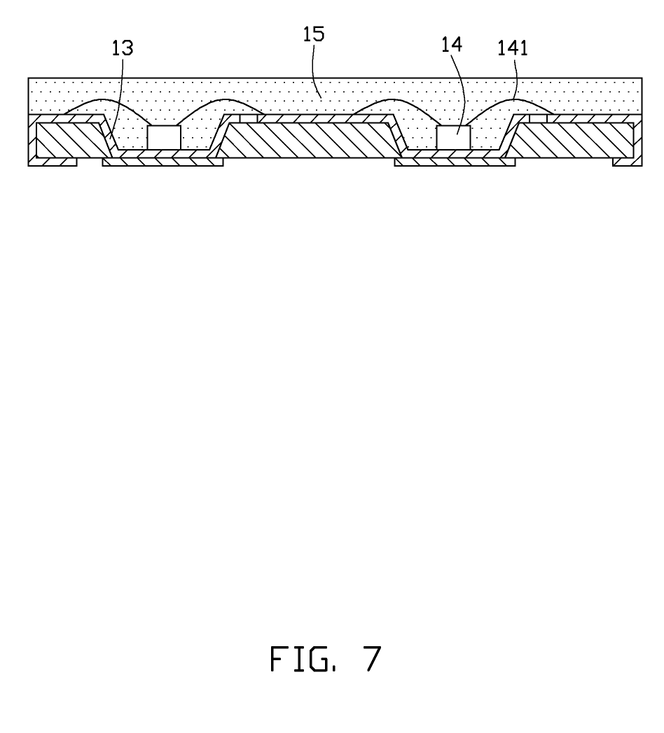

Referring to FIG. 7, the fifth step is to form an encapsulant 15 on the electrode layer 13 and covers the LED chip 14. In the present embodiment, phosphor material can be doped into the encapsulant 15 to convert the wavelength of light emitted from the LED chip 14.

It is to be further understood that even though numerous characteristics and advantages have been set forth in the foregoing description of embodiments, together with details of the structures and functions of the embodiments, the disclosure is illustrative only; and that changes may be made in detail, especially in matters of shape, size, and arrangement of parts within the principles of the disclosure to the full extent indicated by the broad general meaning of the terms in which the appended claims are expressed.

What is claimed is:

1. An LED (light emitting diode) device comprising:
a substrate having a first surface and a second surface, the substrate defining a hole extending through the first surface and the second surface;
a supporting member attached to the second surface of the substrate and covering the hole, the supporting member and the substrate cooperatively defining a cavity;
an electrode layer being arranged on the first surface of the substrate and an inner surface surrounding the cavity;
an LED chip received in the cavity, the LED chip being electrically connected to the electrode layer; and
an encapsulant arranged on the electrode layer and covering the LED chip.

2. The LED device of claim 1, wherein a size of the cavity gradually increases along a direction from the second surface of the substrate towards the first surface.

3. The LED device of claim 1, wherein a height of the substrate ranges from 60 to 300 microns.

4. The LED device of claim 1, wherein a height of the supporting member ranges from 30 to 150 microns.

5. The LED device of claim 1, wherein the supporting member is made of copper.

6. The LED device of claim 1, wherein the electrode layer covers a portion of the supporting member exposed in the through hole, the LED chip being arranged on a portion of the electrode layer covering the supporting member.

7. The LED device of claim 6, wherein the through hole extends into the substrate.

8. The LED device of claim 1, wherein the supporting member has an upper surface connected to the second surface of the substrate and a bottom surface opposite to the upper surface, the upper surface covering the second surface of the substrate, side surfaces of the supporting member being coplanar with side surfaces of the substrate, the electrode layer extending from the first surface of the substrate to the bottom surface of the supporting member along a peripheral edge of the substrate.

9. An LED device comprising:
a substrate defining a through hole;
an electrode layer formed on the substrate and covering a side surface of the substrate defining the through hole;
an LED chip received in the hole and electrically connected to the electrode layer; and
an encapsulant covering the LED chip.

10. The LED device of claim 9, wherein a height of the substrate ranges from 60 to 300 microns.

11. The LED device of claim 9, further comprising a supporting member attached to the substrate under the hole, wherein the supporting member and the hole cooperatively define a cavity receiving the LED chip therein.

12. The LED device of claim 11, wherein a height of the supporting member ranges from 30 to 150 microns.

13. The LED device of claim 11, wherein the supporting member is made of copper.

14. The LED device of claim 9, wherein the electrode layer forms a light reflective cup for the LED chip in the hole.

15. A method for manufacturing an LED device comprising:
providing a substrate, the substrate defining a plurality of through holes;
coupling a supporting member to a side of the substrate to cover the holes, the supporting member and the substrate cooperatively defining a plurality of cavities;
forming an electrode layer on the substrate and inner surfaces of the substrate surrounding the cavities;
arranging a plurality of LED chips in the cavity and electrically connecting the LED chips to the electrode layer; and
encapsulating the LED chips.

16. The method for manufacturing an LED device of claim 15, wherein a height of the substrate ranges from 60 to 300 microns.

17. The method for manufacturing an LED device of claim 15, wherein a height of the supporting member ranges from 30 to 150 microns.

18. The method for manufacturing an LED device of claim 15, wherein the supporting member is made of copper.
